(19) United States
(12) Patent Application Publication
(10) Pub. No.: US 2002/0142582 A1
(43) Pub. Date: Oct. 3, 2002

(54) Method for forming copper lines for semiconductor devices

(76) Inventor: Kil Ho Kim, Kyoungki-do (KR)

Correspondence Address: Pillsbury Winthrop LLP, Intellectual Property Group, Ninth Floor, East Tower, 1100 New York Avenue, N.W., Washington, DC, 20005-3918, US

(21) Appl. No.: 10/103,847

(22) Filed: Mar. 25, 2002

(30) Foreign Application Priority Data
Mar. 30, 2001 (KR) 2001-16941

(51) Int. Cl. H01L 21/4763

(52) U.S. Cl. 438/627; 438/629

(57) ABSTRACT

The present invention discloses a method for forming a copper line of a semiconductor device by using a new damascene process. A copper film is formed over and into trenches formed in a lower insulating layer, a tungsten film is formed on the copper film and planarized, a self-aligned tungsten film pattern is formed over the predetermined copper line region by etching the tungsten film, and a chemical mechanical polishing method is performed using the tungsten film pattern as a hard mask. As a result, the copper line having a generally planar surface and stable conductivity is formed by preventing a misalignment and dishing phenomena, thereby improving device performance, reliability, and process yield.

### BACKGROUND OF THE INVENTION

This application relies for priority upon Korean Patent Application No. 2001-16941 filed on Mar. 30, 2001, the contents of which are herein incorporated by reference in their entirety.

1. Field of the Invention

The present invention relates to a method for forming a copper lines in a semiconductor device and, in particular, to a method for forming copper lines in a semiconductor device that improve the electrical properties and reliability of the copper line, by preventing the excessive removal of the center portion of the copper line also referred to as “dishing” during a chemical mechanical polishing (CMP) process applied to a copper film during production of copper lines using a damascene method.

2. Description of the Background Art

In an integrated circuit, the processes used to form metal lines for contacting devices, connecting devices, and connecting a chip to an external circuit have considerable influence on an operation speed and reliability of the resulting semiconductor device.

As a result of recent developments in semiconductor technologies, metal line processes have become increasingly miniaturized as the size of the devices is reduced. There are also increasing demands for metal line materials and processes having high electrical performance and reliability. Aluminum, aluminum alloys, and copper have all been used as the metal line material in semiconductor devices. In addition, research is actively ongoing with regard to metal organic chemical vapor deposition (MOCVD) techniques for forming metal layers having excellent step coverage.

In general, aluminum materials have been most commonly employed as metal line materials for semiconductor circuits. However, aluminum is not suitable for use in giga-bit level DRAMs due to its relatively high resistance and limitation in reducing the fine line widths necessary for extremely high density devices. In order to solve the foregoing problem, copper, which has higher conductivity than Al, is employed as metal line material despite its slow deposition speed. The slow deposition speed of copper is remarkably improved by by lowering the oxygen and nitrogen content at a surface of a substrate and performing a plasma pretreatment thereon.

However, it is difficult to etch copper. In order to overcome this disadvantage, it has been suggested to use a damascene process for forming a copper line by forming a trench in an interlayer insulating film at a predetermined copper line region, filling the trench with a copper film, and planarizing the copper film using a chemical mechanical polishing (CMP) method.

FIGS. 1A through 1E are cross-sectional diagrams illustrating sequential steps of a conventional method for forming a metal line according to a damascene process.

First, a first interlayer insulating film 12 is formed on a semiconductor substrate 10 having a predetermined substructure.

Thereafter, a metal line contact plug is formed through the first interlayer insulating film to provide electrical contact to a predetermined metal line contact region of the substrate.

A second interlayer insulating film 14 is then formed over the resulting structure.

The second interlayer insulating film 14 is then etched using a metal line etch mask that exposes the intended metal line regions, thus forming a trench 16 (see FIG. 1A).

A diffusion barrier film 18 consisting of Ti/TiN film is then formed over the resulting structure.

A copper film 20 is then formed on the diffusion barrier film 18 and fills up the trench 16. During the initial deposition of the copper film 20, a recessed area, the indicated ‘u’ topology, tends to be formed at the surface of the copper in the trench 16 due to a poor planarization of the copper film 20 (see FIG. 1B).

When the copper film 20 having the desired thickness is formed, the topology is suppressed or mitigated to some degree. Here, the thickness of the copper film 20 necessary to suppress the ‘u’ topology depends on the width and depth of the trench 16 (see FIG. 1C).

Thereafter, the copper film 20 and the diffusion barrier film 18 are planarized using the CMP method to form a diffusion barrier film pattern 21 and a copper line 23 in the trench 16. While only the copper film 20 is being removed using the CMP method, the copper film 20 has a generally planar surface. However, as the CMP progresses and the diffusion barrier film 18 is exposed, the center portion of the copper line 23 develops a recessed surface having a ‘v’ topology as a result of dishing effects (see FIGS. 1D and 1E).

As described above, the conventional method for forming a copper line in a semiconductor device has a disadvantage in that the dishing phenomenon occurs on the copper line formed in the trench due to a polishing rate difference between the copper film and the Ti/TiN film. The recessed areas of the copper lines disrupts the desired planarity of the wafer surface and complicates subsequent processing steps. In addition, the electrical properties of the copper line are degraded, and a process yield and reliability of the resulting devices are reduced.

### SUMMARY OF THE INVENTION

Accordingly, it is an object of the present invention to provide a method for forming a copper line for a semiconductor device with stable electrical properties by utilizing the difference in polishing rate between the self aligned tungsten film pattern corresponding to predetermined copper line regions and the copper film wherein the tungsten film pattern serves as a hard mask to prevent misalignment and dishing during CMP process.

In order to achieve the above-described object of the present invention, there is provided a method for forming a copper line of a semiconductor device, including the steps of: forming an interlayer insulating film on a semiconductor substrate; forming a trench in the interlayer insulating film; forming a diffusion barrier film on the resulting structure depositing a copper layer on the diffusion barrier film; the copper layer being sufficiently thick to fill the trench, the copper layer having a concave surface region located above the trench; depositing a tungsten film on the copper film; planarizing the tungsten film to form a self-aligned tungsten film pattern on the copper layer by removing a portion of the tungsten film, the tungsten film pattern corresponding to the concave surface region; forming a copper line in the trench by a chemical mechanical polishing process to expose a surface of the interlayer insulating film.

### BRIEF DESCRIPTION OF THE DRAWINGS

The present invention will become better understood with reference to the accompanying drawings which are provided by way of illustration only and thus should not be construed to limit the present invention unnecessarily, wherein:

FIGS. 1A through 1E are cross-sectional diagrams illustrating sequential steps of a conventional method for forming a copper line according to a damascene process; and

FIGS. 2A through 2F are cross-sectional diagrams illustrating sequential steps of a method for forming a copper line by a damascene process in accordance with the present invention.

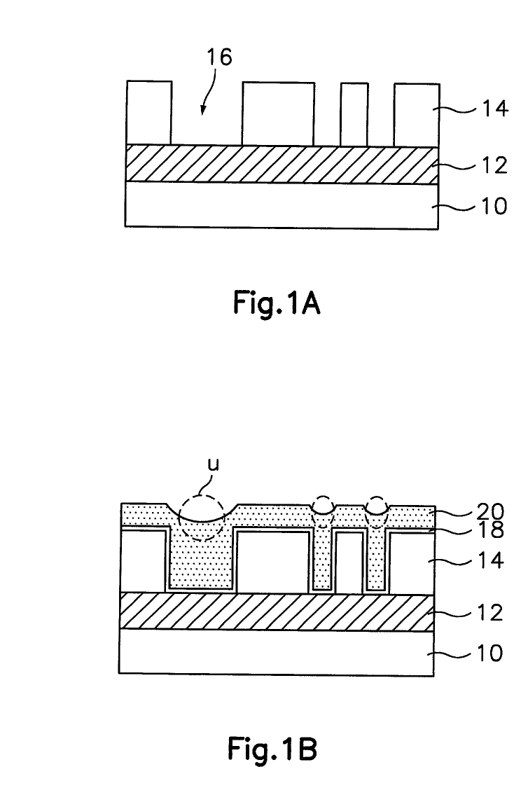

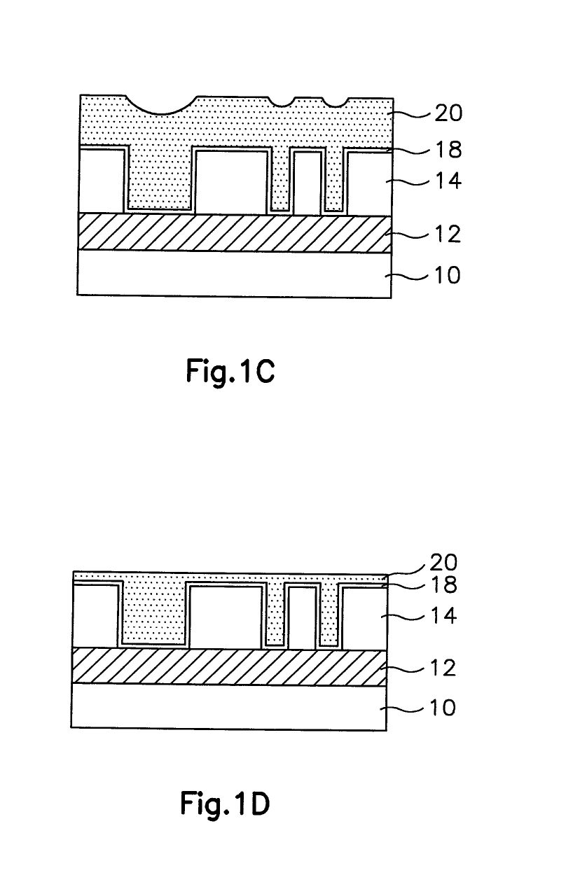

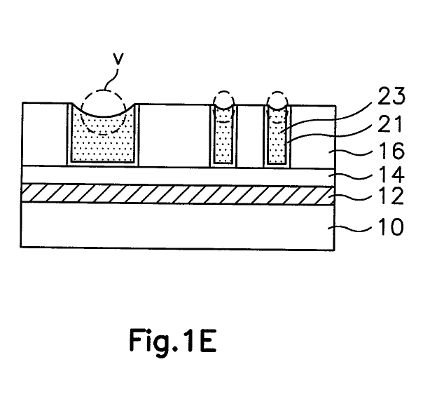

### DETAILED DESCRIPTION OF THE PREFERRED EMBODIMENTS

A method for forming a copper line of a semiconductor device in accordance with the present invention will now be described in detail with reference to the accompanying drawings.

A substructure consisting of a word line, bit line and capacitor is first formed on a semiconductor substrate 100 and a first interlayer insulating film 102 is then formed on the resulting structure.

A metal line contact plug (not shown) is then formed through first interlayer insulating film 102 to make contact to a predetermined metal line contact region of the substrate and a second interlayer insulating film 104 is then formed over the resulting structure.

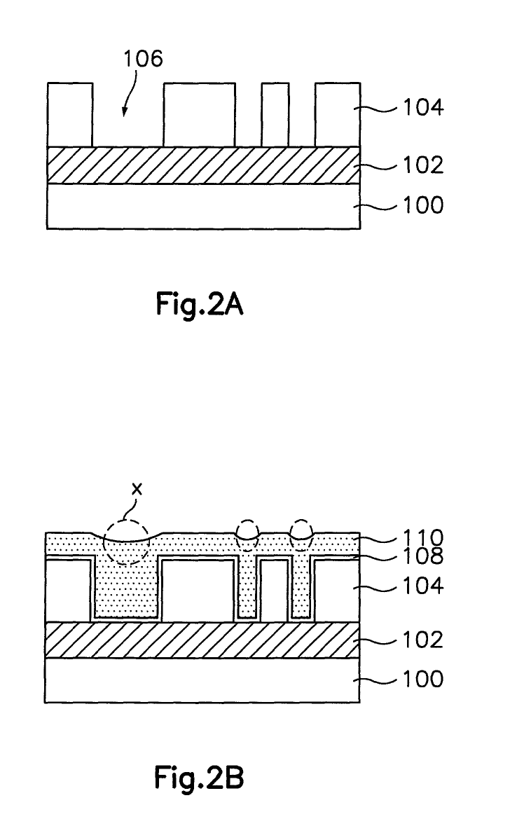

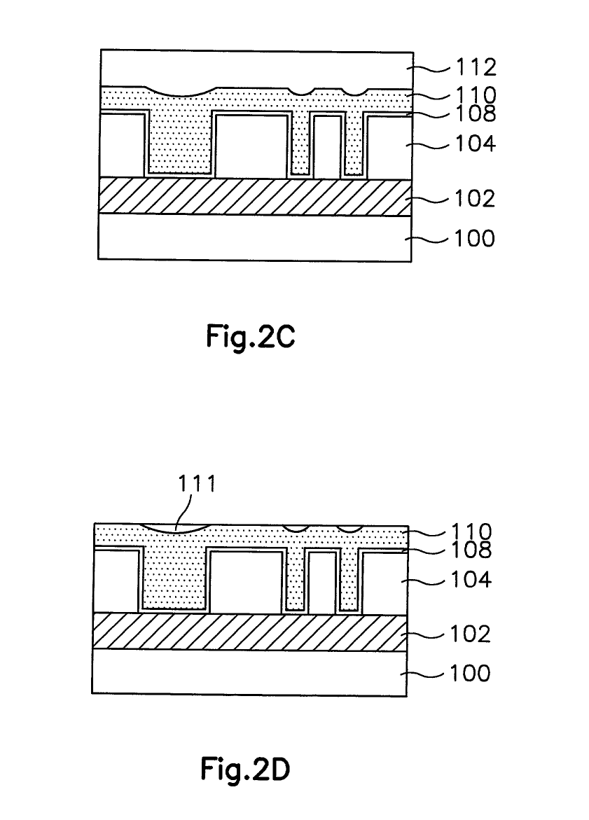

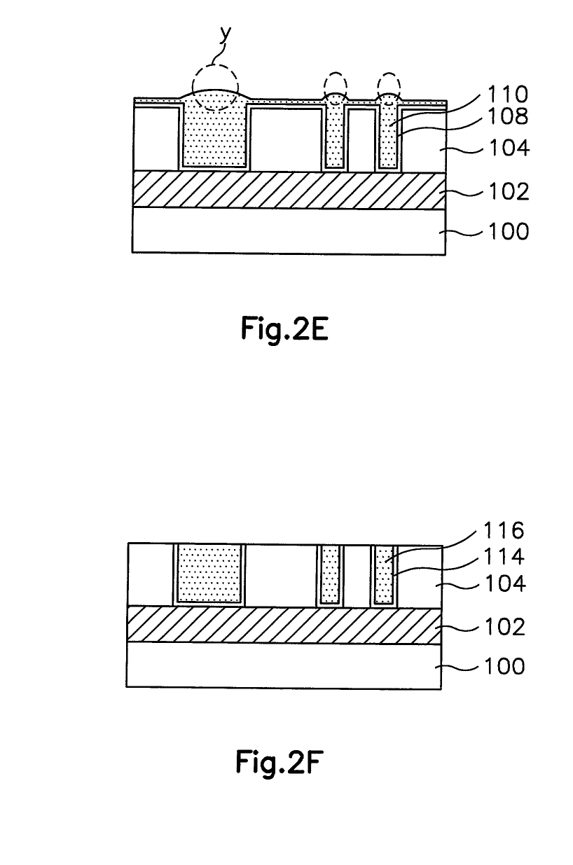

Thereafter, a trench 106 exposing a predetermined metal line region and a metal line contact plug (not shown) is formed by etching the second interlayer insulating film 104 (see FIG. 2A).

A diffusion barrier film 108, preferably a Ti/TiN film, is then formed over the resulting structure.

A copper film 110 is then deposited on the diffusion barrier film 108 to fill up the trench 106. Here, the copper film 110 has a sufficient thickness to fill up the trench 106, and a concave ‘x’ topology is formed on the surface of the copper film 110 above the trench 106 (see FIG. 2B).

Thereafter, a tungsten film 112 is deposited on the copper film 110, and the resulting structure is planarized. Here, the tungsten film 112 has a superior planarization properties compared to the copper film 110, thus removing the ‘x’ topology to provide a more planar surface on the resulting structure (see FIG. 2C).

The tungsten film 112, with the exception of a portion above a copper line region, is then removed using a chemical mechanical polishing (CMP) method or an etchback process, preferably using a SF₆ gas activating plasma, thereby forming a tungsten film pattern 111. At this time, the tungsten film pattern 111 is self-aligned along the concave regions above the trench 106 where a copper line will be formed (see FIG. 2D).

Additional portions of the copper film 110 are then removed by CMP using the tungsten film pattern 111 as a hard mask. Given the differences in relative hardness between the copper and the tungsten, most CMP processes will result in a higher copper polishing rate. This CMP process is, however, preferably performed using a polishing composition that further enhances the polishing rate for the copper film 110.

Because the copper film 110 is being removed by the CMP at a higher rate than the tungsten film pattern 111, a convex ‘y’ topology is produced in the copper film 110 as the tungsten is removed (see FIG. 2E).

The CMP process is then continued until the copper film 110 and the diffusion barrier film 108 are removed to expose the surface of the second interlayer insulating film 106, thereby forming a diffusion barrier film pattern 114 and a copper line 116 in the trench 106. By utilizing the difference between the polishing rates of the copper film 110, diffusion barrier film 108 and the second interlayer insulating film 106 the CMP process according to the present invention produces a copper line 116 with a substantial planar surface (see FIG. 2F).

As discussed earlier, in accordance with the present invention, when the copper line is formed by a conventional damascene process, the surface of the copper film develops concave topologies reflecting both the topology of the lower layer and dishing effects during CMP processing. In the present invention, however, a tungsten film is formed on the copper film and planarized to form a self-aligned tungsten film pattern above the predetermined copper line regions with the subsequent CMP process utilizing the tungsten film pattern as a sacrificial hard mask. As a result, a copper line having stable conductivity is formed by preventing or suppressing misalignment and dishing phenomena, and the operational properties and process yield of the resulting device are improved.

As the present invention may be embodied in several forms without departing from the spirit or essential characteristics thereof, it should also be understood that the above-described embodiment is not necessarily limited by any of the particular details of the foregoing description, unless otherwise specified, but rather should be construed broadly within the spirit and scope of the appended claims, and therefore all changes and modifications that fall within the metes and bounds of the claims, or equivalents of such meets metes and bounds, are therefore intended to be embraced by the appended claims.

What is claimed is:

1. A method for forming a copper line on a semiconductor device, comprising the steps of:
forming an interlayer insulating film on a semiconductor substrate;
forming a trench in the interlayer insulating film;
forming a diffusion barrier film on the resulting structure
depositing a copper layer on the diffusion barrier film, the copper layer being sufficiently thick to fill the trench, the copper layer having a concave surface region located above the trench;
depositing a tungsten film on the copper film;
planarizing the tungsten film to form a self-aligned tungsten film pattern on the copper layer by removing a portion of the tungsten film, the tungsten film pattern corresponding to the concave surface region;
forming a copper line in the trench by a chemical mechanical polishing process to expose a surface of the interlayer insulating film.

2. The method according to claim 1, wherein the diffusion barrier film comprises a Ti/TiN film.

3. The method according to claim 1, wherein the step of forming the self-aligned tungsten film pattern further comprises chemical mechanical polishing under conditions that provide a copper polishing rate and a tungsten polishing rate, the copper polishing rate being greater than the tungsten polishing rate.

4. The method according to claim 1, wherein the step of forming the self-aligned tungsten film pattern further comprises dry etching the tungsten film using an activated SF₆ plasma gas.

5. The method according to claim 1, wherein the step of forming the copper line in the trench further comprises a chemical mechanical polishing process utilizing an abrasive which has higher polishing selectivity for copper than tungsten.

6. The method according to claim 1, wherein the step forming the copper line further utilizes a chemical mechanical polishing process that produces different polishing rates for the tungsten film pattern, the copper layer, the diffusion barrier film, and the interlayer insulating film.
